(19) United States
(12) Patent Application Publication
(10) Pub. No.: US 2026/0025619 A1
(43) Pub. Date: Jan. 22, 2026

(54) SIGNAL PROCESSING SYSTEM AND SIGNAL PROCESSING METHOD

(71) Applicant: Chicony Electronics Co., Ltd., New Taipei City (TW)

(72) Inventors: Wen-Chang Lin, New Taipei City (TW); Chun-Wei Chu, New Taipei City (TW)

(21) Appl. No.: 19/174,533

(22) Filed: Apr. 9, 2025

(30) Foreign Application Priority Data
Jul. 17, 2024 (TW) 113126809

(51) Int. Cl. H04R 3/04; H03C 3/09; H04R 3/00

(52) U.S. Cl. CPC H04R 3/04; H03C 3/09; H04R 3/005

(57) ABSTRACT

A signal processing system and a signal processing method are provided. The signal processing method includes: in response to that a mode selection element receives a turn-off signal, outputting a first signal by the mode selection element; in response to that a switching element receives the first signal, switching from outputting a digital source signal to outputting a virtual signal by the switching element; in response to that a first delay element receives the first signal, outputting a first delay signal by the first delay element, where the first delay signal reaches a first voltage after a first delay time; and in response to that the first delay signal reaches the first voltage, stop outputting an output voltage by a power element.

### CROSS-REFERENCE TO RELATED APPLICATION

This non-provisional application claims priority under 35 U.S.C. § 119 (a) to patent application No. 113126809 filed in Taiwan, R.O.C. on Jul. 17, 2024, the entire contents of which are hereby incorporated by reference.

### BACKGROUND

### Technical Field

The instant disclosure relates to a digital signal processing system and a digital signal processing method, in particular, to a digital signal processing system and a digital signal processing method in which the instability phenomenon of the digital signal source is considered.

### Related Art

Upon performing digital signal transmissions, a physical switch may be needed to stop or to start the device which generates the digital signals. However, when the device which generates the digital signals is stopping or starting, unstable signals may be generated to cause unexpected issues. For example, when a digital microphone is applied to transmit audio signals, a physical switch is used to stop or start the digital microphone. However, during the switching process, the unstable signals generated by the digital microphone will cause short audio popping, thereby affecting users' experiences.

### SUMMARY

In view of this, according to some embodiments of the instant disclosure, a signal processing system and a signal processing method are provided to address technical issues which are currently encountered.

In view of this, according to some embodiments of the instant disclosure, a signal processing system is provided. The signal processing system comprises a mode selection element, a switching element, a first delay element, and a power element. The mode selection element is configured to, in response to receiving a turn-off signal, output a first signal; the switching element is coupled to the mode selection element, and the switching element is configured to, in response to receiving the first signal, switch from outputting a digital source signal to outputting a virtual signal; the first delay element is coupled to the mode selection element, and the first delay element is configured to, in response to receiving the first signal, output a first delay signal, wherein the first delay signal reaches a first voltage after a first delay time; the power element is coupled to the first delay element, and the power element is configured to, in response to that the first delay signal reaches the first voltage, stop outputting an output voltage.

According to some embodiments of the instant disclosure, a signal processing method adapted for a signal processing method is provided. The signal processing system comprises a mode selection element, a switching element coupled to the mode selection element, a first delay element coupled to the mode selection element, and a power element coupled to the first delay element. The signal processing method comprises: in response to receiving a turn-off signal, outputting a first signal by the mode selection element; in response to receiving the first signal, switching from outputting a digital source signal to outputting a virtual signal by the switching element; in response to receiving the first signal, outputting a first delay signal by the first delay element, wherein the first delay signal reaches a first voltage after a first delay time; and in response to that the first delay signal reaches the first voltage, stopping outputting an output voltage by the power element.

Based on above, in the signal processing control system and the signal processing method according to some embodiments of the instant disclosure, the first delay signal is applied to switch the output of the signal to a virtual signal before the element which generates a digital source signal is turned off. Therefore, unstable signals which may be generated upon turning off the element which generates the digital source signal can be prevented from being transmitted to the back-end codec.

### BRIEF DESCRIPTION OF THE DRAWINGS

The disclosure will become more fully understood from the detailed description given herein below for illustration only, and thus not limitative of the disclosure, wherein:

FIG. 1 illustrates a block diagram of a signal processing system according to an exemplary embodiment of the instant disclosure;

FIG. 2 illustrates a block diagram of a signal processing system according to an exemplary embodiment of the instant disclosure;

FIG. 3 illustrates a block diagram of a circuit of a signal processing system according to an exemplary embodiment of the instant disclosure;

FIG. 4 illustrates a schematic view showing signal switching according to an exemplary embodiment of the instant disclosure;

FIG. 5 illustrates a schematic view showing signal switching according to an exemplary embodiment of the instant disclosure;

FIG. 6 illustrates a flowchart of a signal processing method according to an exemplary embodiment of the instant disclosure;

FIG. 7 illustrates a flowchart of a signal processing method according to an exemplary embodiment of the instant disclosure;

FIG. 8 illustrates a flowchart of a signal processing method according to an exemplary embodiment of the instant disclosure;

FIG. 9 illustrates a flowchart of a signal processing method according to an exemplary embodiment of the instant disclosure; and

FIG. 10 illustrates a flowchart of a signal processing method according to an exemplary embodiment of the instant disclosure.

### DETAILED DESCRIPTION

The aforementioned and other technical contents, features and effects of the instant disclosure will be clearly presented in the following detailed description of the embodiments with reference to the drawings. The thickness or size of each component in the drawings is exaggerated, omitted, or schematically expressed for the purpose of understanding and reading by persons having ordinary skills in the art, and the size of each component is not the actual size of the component and is not intended to limit the conditions under which the instant disclosure can be implemented, and thus the size of the component does not have substantive technical meaning. Moreover, it is understood that, any structural modifications, changes in proportions, or adjustments in size should still fall within the scope of the technical content disclosed in the instant disclosure without affecting the effects that can be produced and the purposes that can be achieved by the instant disclosure. The same reference numbers will be used throughout the drawings to refer to the same or similar elements. The term “coupled/coupling” mentioned in the following embodiments may refer to any direct or indirect connection.

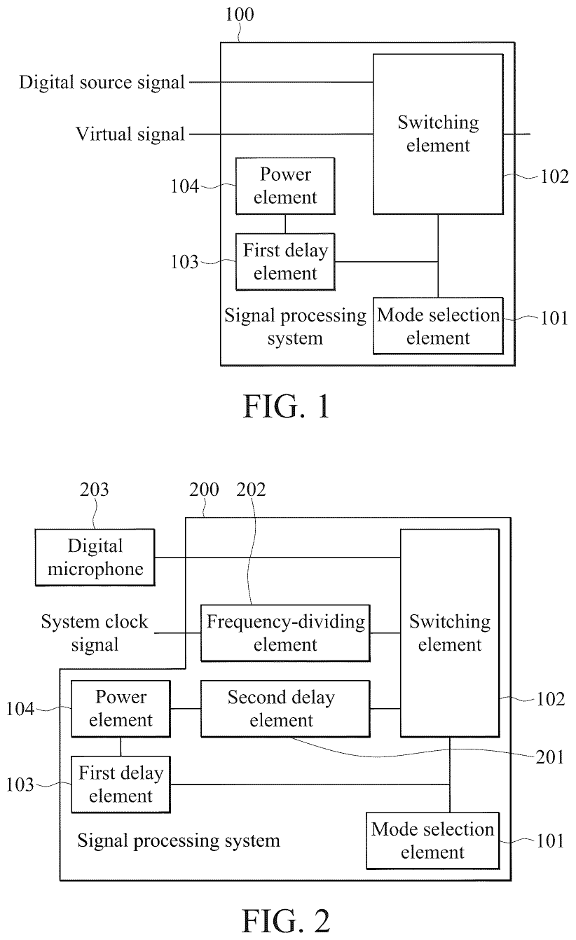

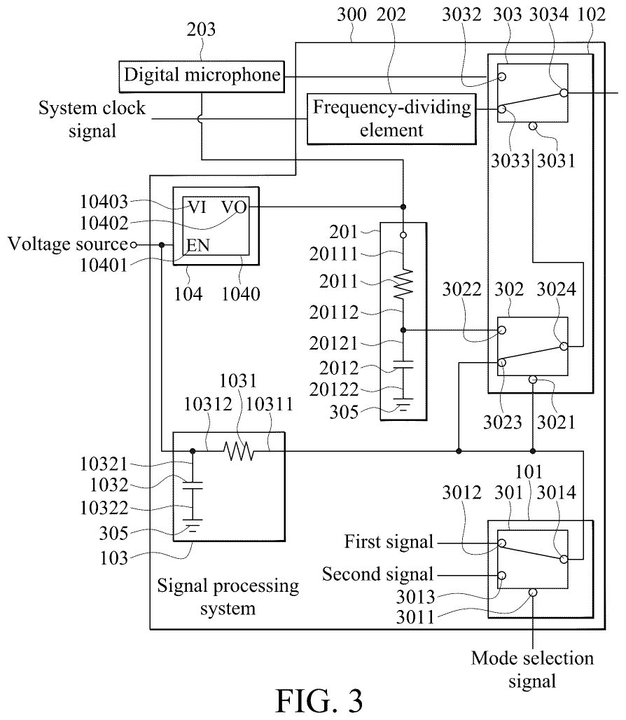

FIG. 1 illustrates a block diagram of a signal processing system according to an exemplary embodiment of the instant disclosure. FIG. 3 illustrates a block diagram of a circuit of a signal processing system according to an exemplary embodiment of the instant disclosure. Refer to FIG. 1 and FIG. 3. The signal processing system 100 comprises a mode selection element 101, a switching element 102, a first delay element 103, and a power element 104. The mode selection element 101 is configured to receive a mode selection signal externally, wherein the mode selection signal comprises a turn-off signal and a startup signal. The turn-off signal may be a high voltage representing logic 1, and the startup signal may be a low voltage representing logic 0, but the instant disclosure is not limited thereto. The mode selection element 101 is configured to, in response to that the mode selection element 101 receives the turn-off signal, output a first signal, and the mode selection element 101 is configured to, in response to that the mode selection element 101 receives the startup signal, output a second signal.

Refer to FIG. 3. In some embodiments of the instant disclosure, as the signal processing system 300 illustrated in FIG. 3, the mode selection element 101 comprises an analog switch 301. The analog switch 301 comprises a control terminal 3011, an input terminal 3012, an input terminal 3013, and an output terminal 3014. The input terminal 3012 receives the first signal, and the input terminal 3013 receives the second signal. When the control terminal 3011 receives the high voltage representing logic 1 (the turn-off signal), the analog switch 301 connects the output terminal 3014 to the input terminal 3012 to allow the output terminal 3014 to output the first signal. When the control terminal 3011 receives the low voltage representing logic 0 (the startup signal), the analog switch 301 connects the output terminal 3014 to the input terminal 3013 to allow the output terminal 3014 to output the second signal. The first signal for example may be a low voltage representing logic 0, and the second signal for example may be a high voltage representing logic 1. It should be noted that, the startup signal and the first signal may be different voltage levels, and the turn-off signal and the second signal may also be different voltage levels.

The switching element 102 is coupled to the mode selection element 101, and the switching element 102 is configured to receive a digital source signal and a virtual signal. The switching element 102 outputs the virtual signal or the digital source signal according to the first signal or the second signal outputted by the mode selection element 101. The first delay element 103 is coupled to the mode selection element 101. The first delay element 103 is configured to, in response to that the first delay element 103 receives the first signal, output a first delay signal, wherein the first delay signal reaches a first voltage after a first delay time. The power element 104 is coupled to the first delay element 103. The power element 104 is configured to, in response to that the first delay signal reaches the first voltage, stop outputting an output voltage.

In the following paragraphs, descriptions and accompanied drawings are provided to show how the cooperation between modules of the signal processing system 100 and the signal processing method according to some embodiments of the instant disclosure can be achieved.

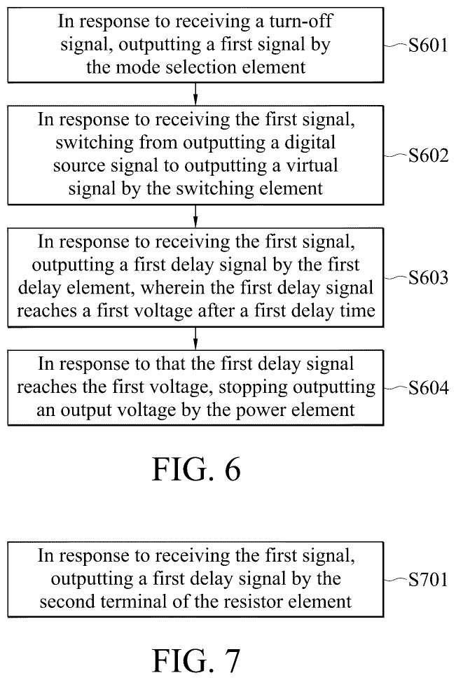

FIG. 6 illustrates a flowchart of a signal processing method according to an exemplary embodiment of the instant disclosure. Refer to FIG. 1 and FIG. 6. In the embodiment illustrated in FIG. 6, the signal processing method comprises steps S601 to S604. In the step S601, in response to receiving a turn-off signal, outputting a first signal to the switching element 102 and the first delay element 103 by the mode selection element 101. In the step S602, in response to receiving the first signal, switching from outputting a digital source signal to outputting a virtual signal by the switching element 102.

In the step S603, in response to receiving the first signal, outputting a first delay signal by the first delay element 103, wherein the first delay signal reaches a first voltage after a first delay time. In the step S604, in response to that the first delay signal reaches the first voltage, stopping outputting an output voltage by the power element 104. At this moment, the element which generates the digital source signal stops generating the digital source signal.

In the embodiments mentioned above, the first delay signal is applied to switch the output of the signal to the virtual signal before the element which generates a digital source signal is turned off. Therefore, unstable signals which may be generated upon turning off the element which generates the digital source signal can be prevented from being transmitted to the back-end codec (not shown).

Refer to FIG. 3. In some embodiments of the instant disclosure, the power element 104 comprises a low dropout regulator (LDO) 1040. The low dropout regulator 1040 comprises an input terminal 10403 (symbol: VI), an enable terminal 10401 (symbol: EN), and an output terminal 10402 (symbol: VO). The input terminal 10403 of the low dropout regulator 1040 is configured to receive an input voltage. The enable terminal 10401 of the low dropout regulator 1040 is coupled to the first delay element 103. When the voltage received by the enable terminal 10401 is less than an enable low voltage level, the low dropout regulator 1040 is disabled to stop outputting the output voltage. The enable low voltage level may be 0.4 V (depending on the design of the low dropout regulator 1040, but the instant disclosure is not limited thereto). In this embodiment, the first voltage is the enable low voltage level. The element which generates the digital source signal is supplied with electricity using the low dropout regulator 1040. Therefore, when the low dropout regulator 1040 is disabled to stop outputting the output voltage, the element which generates the digital source signal stops generating the digital source signal. In this embodiment, the signal processing method comprises: in response to that the voltage received by the enable terminal 10401 reaches the first voltage, stopping outputting the output voltage by the low dropout regulator 1040.

Refer to FIG. 3. In some embodiments of the instant disclosure, the digital source signal is a digital audio signal generated by a digital microphone 203 based on the sounds received by the digital microphone 203. The digital microphone 203 is supplied with electricity using the low dropout regulator 1040 of the power element 104. It is understood that, when the digital microphone 203 is turning off, the unstable signals caused by the digital source signal will cause the audio popping phenomenon, thereby making the user uncomfortable. In the embodiments mentioned above, the first delay signal is applied to switch the output of the signal to a virtual signal and output the virtual signal to the back-end codec before the digital microphone 203 is turned off. Therefore, by the virtual signal to replace the digital source signal which may cause unstable signals upon turning off the digital microphone 203, the audio popping phenomenon can be prevented.

In some embodiments of the instant disclosure, the virtual signal is a frequency-dividing signal of a system clock signal, wherein the system clock signal is the clock signal of the codec, and the frequency of the frequency-dividing signal of the system clock signal may be the frequency of the system clock signal divided by any positive integer greater than 1. When the virtual signal is the frequency-dividing signal of the system clock signal, the virtual signal is synchronized with the clock signal of the codec.

Refer to FIG. 1 and FIG. 3 again. In some embodiments of the instant disclosure, the signal processing system 100 comprises a frequency-dividing element 202, and the frequency-dividing element 202 is adapted to receive the system clock signal and coupled to the switching element 102. The frequency-dividing element 202 is configured to perform a dividing operation on the system clock signal based on a divisor to obtain the frequency-dividing signal, wherein the divisor is a power of 2; in other words, in this embodiment, the divisor is 2ⁿ, wherein n is a positive integer. In this embodiment, the signal processing method comprises performing a dividing operation on the system clock signal based on a divisor to obtain the frequency-dividing signal to obtain the frequency-dividing signal by the frequency-dividing element 202, wherein the divisor is 2ⁿ, and n is a positive integer.

FIG. 7 illustrates a flowchart of a signal processing method according to an exemplary embodiment of the instant disclosure. Refer to FIG. 1, FIG. 3, and FIG. 7. Following the embodiment in which the first signal is the low voltage representing logic 0 and the power element 104 comprises the low dropout regulator 1040, the first delay element 103 comprises a resistor element 1031 and a capacitor element 1032. A first terminal 10311 of the resistor element 1031 is coupled to the mode selection element 101, and a second terminal 10312 of the resistor element 1031 is coupled to a first terminal 10321 of the capacitor element 1032 and a voltage source. A second terminal 10322 of the capacitor element 1032 is coupled to a ground terminal 305. During the period of the power element 104 outputting the output voltage, if the mode selection element 101 outputs the first signal (the low voltage representing logic 0), the voltage on the second terminal 10312 of the resistor element 1031 starts to decrease because the capacitor element 1032 is discharged through the resistor element 1031. The first delay signal is the voltage change signal on the second terminal 10312 of the resistor element 1031. When the voltage on the second terminal 10312 of the resistor element 1031 is less than the enable low voltage level of the low dropout regulator 1040, the low dropout regulator 1040 is disabled to stop outputting the output voltage. In this embodiment, the step S603 comprises a step S701. In the step S701, in response to receiving the first signal, outputting a first delay signal by the second terminal 10312 of the resistor element 1031.

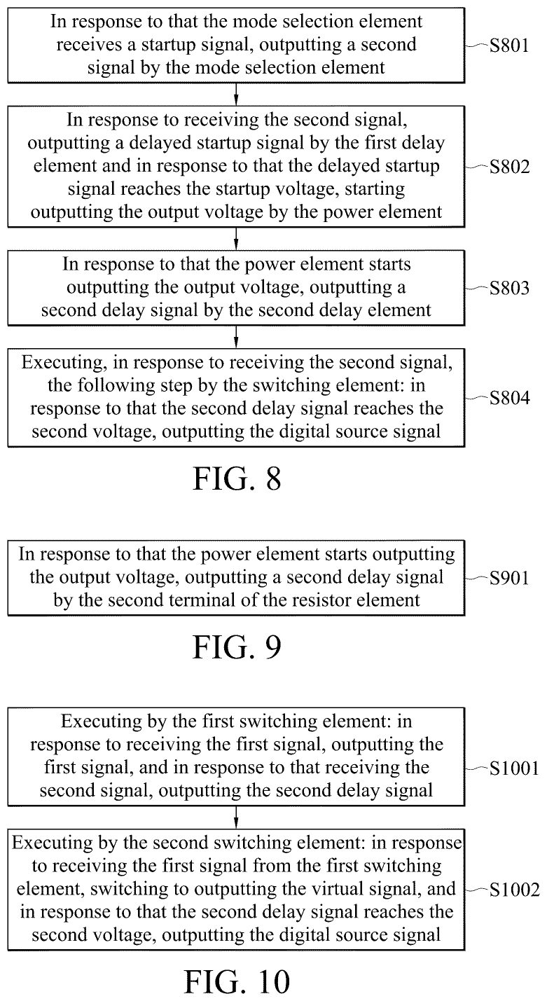

FIG. 2 illustrates a block diagram of a signal processing system according to an exemplary embodiment of the instant disclosure. FIG. 8 illustrates a flowchart of a signal processing method according to an exemplary embodiment of the instant disclosure. Refer to FIG. 2. As compared with the signal processing system 100 shown in FIG. 1, the signal processing system 200 shown in FIG. 2 further comprises a second delay element 201 and the frequency-dividing element 202. The frequency-dividing element 202 is already described in the foregoing embodiments, which will not be repeated here. In the embodiment illustrated in FIG. 2, the first delay element 103 is configured to, in response to that the first delay element 103 receives the second signal, output a delayed startup signal, wherein the delayed startup signal reaches a startup voltage after a delayed startup time; the power element 104 is configured to, in response to that the delayed startup signal reaches the startup voltage, start outputting the output voltage. The second delay element 201 is coupled to the power element 104. The second delay element 201 is configured to, in response to that the power element 104 starts outputting the output voltage, output a second delay signal, wherein the second delay signal reaches a second voltage after a second delay time. The switching element 102 is configured to coupled to the second delay element 201.

In this embodiment, the signal processing method comprises steps S801 to S804. In the step S801, in response to that the mode selection element 101 receives a startup signal, outputting a second signal by using the mode selection element 101. In the step S802, in response to that the first delay element 103 receives the second signal, outputting a delayed startup signal by using the first delay element 103, wherein the delayed startup signal reaches a startup voltage after a delayed startup time, and in response to that the delayed startup signal reaches the startup voltage, starting outputting the output voltage by the power element 104. In the step S803, in response to that the power element 104 starts outputting the output voltage, outputting a second delay signal by the second delay element 201, wherein the second delay signal reaches a second voltage after a second delay time. In the step S804, executing, in response to receiving the second signal, the following step by the switching element 102: in response to that the second delay signal reaches the second voltage, outputting the digital source signal.

Refer to FIG. 3. Following the embodiment in which the second signal is the high voltage representing logic 1, the power element 104 comprises the low dropout regulator 1040, and the first delay element 103 comprises the resistor element 1031 and the capacitor element 1032, the low dropout regulator 1040 is configured such that when the voltage received by the enable terminal 10401 is pulled to be greater than an enable high voltage level of the low dropout regulator 1040, the low dropout regulator 1040 is enabled and starts outputting the output voltage. The enable high voltage level, for example, is 1 V (depending on the design of the low dropout regulator 1040, but the instant disclosure is not limited thereto).

During the period where the voltage on the second terminal 10312 of the resistor element 1031 is less than the enable low voltage level of the low dropout regulator 1040, the low dropout regulator 1040 is disabled to stop outputting the output voltage. If the mode selection element 101 outputs the second signal (the high voltage representing logic 1), the voltage on the second terminal 10312 of the resistor element 1031 starts to increase because the capacitor element 1032 is charged through the resistor element 1031. The delayed startup signal is the voltage change signal on the second terminal 10312 of the resistor element 1031 which is generated because the capacitor element 1032 is charged. When the voltage received by the enable terminal 10401 is pulled to be greater than the enable high voltage level of the low dropout regulator 1040, the low dropout regulator 1040 is enabled to start outputting the output voltage. The startup voltage is the enable high voltage level. The element which generates the digital source signal is supplied with electricity by the low dropout regulator 1040. Therefore, when the low dropout regulator 1040 is enabled to start outputting the output voltage, the element which generates the digital source signal starts generating the digital source signal. In this embodiment, the step S802 comprises following steps: in response to receiving the second signal, outputting the delayed startup signal by the second terminal 10312 of the resistor element 1031.

FIG. 9 illustrates a flowchart of a signal processing method according to an exemplary embodiment of the instant disclosure. Refer to FIG. 2, FIG. 3, FIG. 8, and FIG. 9. Following the embodiment in which the power element 104 comprises the low dropout regulator 1040, the second delay element 201 comprises a resistor element 2011 and a capacitor element 2012. A first terminal 20111 of the resistor element 2011 is coupled to the output terminal 10402 of the low dropout regulator 1040 of the power element 104, a second terminal 20112 of the resistor element 2011 is coupled to a first terminal 20121 of the capacitor element 2012, and a second terminal 20112 of the capacitor element 2012 is coupled to the ground terminal 305. When the low dropout regulator 1040 of the power element 104 is activated, the first terminal 20111 of the resistor element 2011 is pulled to the output voltage of the low dropout regulator 1040. Therefore, the capacitor element 2012 is charged through the resistor element 2011, and the voltage on the second terminal 20112 of the resistor element 2011 starts to increase. The second delay signal is the voltage change signal on the second terminal 20112 of the resistor element 2011. The second delay signal is increased to the second voltage after the second delay time. In this embodiment, the step S803 comprises a step S901. In the step S901, in response to that the power element 104 starts outputting the output voltage, outputting a second delay signal by the second terminal 20112 of the resistor element 2011.

Refer to FIG. 3. Upon activating he digital microphone 203, a period of startup time is needed. In the period that the startup time is not reached after the digital microphone is activated, the internal components of the digital microphone 203 may output unstable signals due current change. When the unstable signals are played through the digital microphone 203, the audio popping phenomenon may occur. In some embodiments of the instant disclosure, the second delay time may be set to be greater than the startup time of the digital microphone 203 (for example, depending on the startup time needed for different types of the digital microphone 203, the resistance of the resistor element 2011 and the capacitance of the capacitor element 2012 can be adjusted to adjust the second delay time).

FIG. 10 illustrates a flowchart of a signal processing method according to an exemplary embodiment of the instant disclosure. Refer to FIG. 3 and FIG. 10. In some embodiments of the instant disclosure, the switching element 102 comprises a first switching element 302 and a second switching element 303. In this embodiment, the first switching element 302 is an analog switch and comprises a control terminal 3021, an input terminal 3022, an input terminal 3023, and an output terminal 3024. The control terminal 3021 and the input terminal 3023 of the first switching element 302 is coupled to the mode selection element 101, and the input terminal 3022 is coupled to the second delay element 201. The first switching element 302 is configured to, in response to that the control terminal 3021 receives the first signal, connect the output terminal 3024 to the input terminal 3023 to allow the output terminal 3024 to output the first signal; and the first switching element 302 is configured to, in response to that the control terminal 3021 receives the second signal, connect the output terminal 3024 to the input terminal 3022 to allow the output terminal 3024 to output the second delay signal.

In this embodiment, the second switching element 303 is an analog switch and comprises a control terminal 3031, an input terminal 3032, an input terminal 3033, and an output terminal 3034. The control terminal 3031 of the second switching element 303 is coupled to the output terminal 3024 of the first switching element 302. The input terminal 3032 is coupled to the digital microphone 203 to receive the digital source signal. The input terminal 3033 is coupled to the frequency-dividing element 202 to receive the virtual signal. The second switching element 303 is configured to execute: in response to receiving the first signal from the first switching element 302, switching to outputting the virtual signal, and in response to that the second delay signal reaches the second voltage, outputting the digital source signal. In this embodiment, the signal processing method comprises steps S1001 and S1002. In the step S1001, executing by the first switching element 302: in response to receiving the first signal, outputting the first signal, and in response to that receiving the second signal, outputting the second delay signal. In the step S1002, executing by the second switching element 303: in response to receiving the first signal from the first switching element 302, switching to outputting the virtual signal, and in response to that the second delay signal reaches the second voltage, outputting the digital source signal.

In some embodiments of the instant disclosure, the first signal is a low voltage representing logic 0, and the second signal is a high voltage representing logic 1. The second switching element 303 is configured to connect the output terminal 3034 to the input terminal 3033 when the control terminal 3031 receives the low voltage representing logic 0, and the second switching element 303 is configured to connect the output terminal 3034 to the input terminal 3032 when the control terminal 3031 receives the high voltage representing logic 1. In this embodiment, the second voltage is a high voltage representing logic 1. In this embodiment, based on the foregoing configuration, when the second switching element 303 receives the first signal (the low voltage representing logic 0) from the first switching element 302, the second switching element 303 connects the output terminal 3034 to the input terminal 3033 so as to be switched to outputting the virtual signal. When the second switching element 303 receives the second delay signal from the first switching element 302, because the second delay signal is a low voltage representing logic 0 at the beginning, the second switching element 303 outputs the virtual signal. Until the second delay signal reaches the second voltage (in this embodiment, the high voltage representing logic 1), the second switching element 303 connects the output terminal 3034 to the input terminal 3032 so as to be switched to outputting the digital source signal.

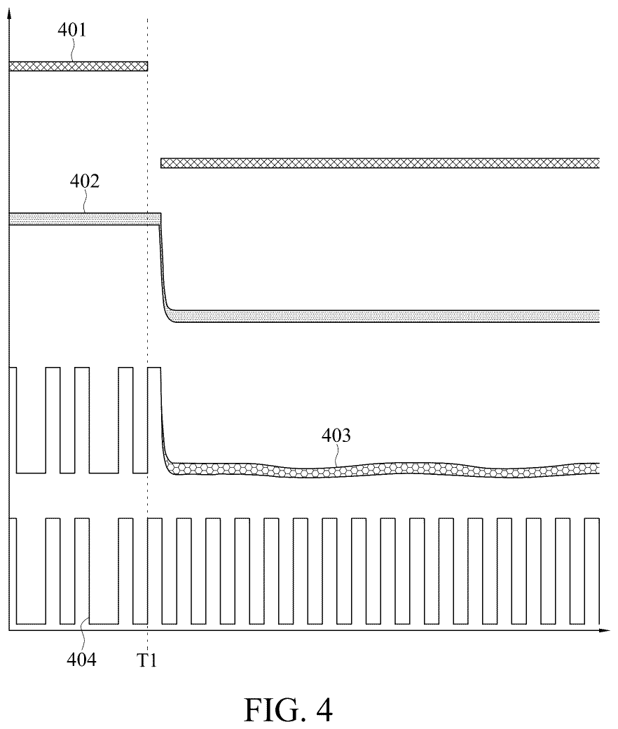

FIG. 4 illustrates a schematic view showing signal switching according to an exemplary embodiment of the instant disclosure. Refer to FIG. 3, FIG. 4, and FIG. 6. In some embodiments of the instant disclosure, in the signal processing system 300, the first signal is a low voltage representing logic 0, and the second signal is a high voltage representing logic 1. The virtual signal is the frequency-dividing signal of the system clock signal. The second switching element 303 is configured to connect the output terminal 3034 to the input terminal 3033 when the control terminal 3031 receives the low voltage representing logic 0, and the second switching element 303 is configured to connect the output terminal 3034 to the input terminal 3032 when the control terminal 3031 receives the high voltage representing logic 1. In this embodiment, the second voltage is the high voltage representing logic 1. The signal 401 is the signal received by the control terminal 3031 of the second switching element 303, the signal 402 is the output signal of the low dropout regulator 1040, the signal 403 is a signal received by the input terminal 3032 of the second switching element 303 which is outputted from the digital microphone 203, and the signal 404 is the output signal of the output terminal 3034 of the second switching element 303.

After the mode selection element 101 outputs the first signal to the switching element 102 and the first delay element 103 in response to receiving the turn-off signal (the step S601), the signal received by the control terminal 3031 of the second switching element 303 is illustrated as the signal 401, in which the signal 401 is changed from a high voltage representing logic 1 to a low voltage representing logic 0 at the time T1. At this moment, as the signal 404 shown in FIG. 4, at the time T1, the output terminal 3034 of the second switching element 303 is changed to outputting the virtual signal (the step S602). As the signal 402 shown in FIG. 4, when the voltage on the second terminal 10312 of the resistor element 1031 is less than the enable low voltage level of the low dropout regulator 1040, the low dropout regulator 1040 is disabled to stop outputting the output voltage (the step S604). Moreover, as illustrated by the signal 403, after the low dropout regulator 1040 is disabled to stop outputting the output voltage, the input terminal 3032 of the second switching element 303 does not receive the signal outputted from the digital microphone 203 (because the digital microphone 203 stops operation when the digital microphone 203 does not receive the output voltage of the low dropout regulator 1040).

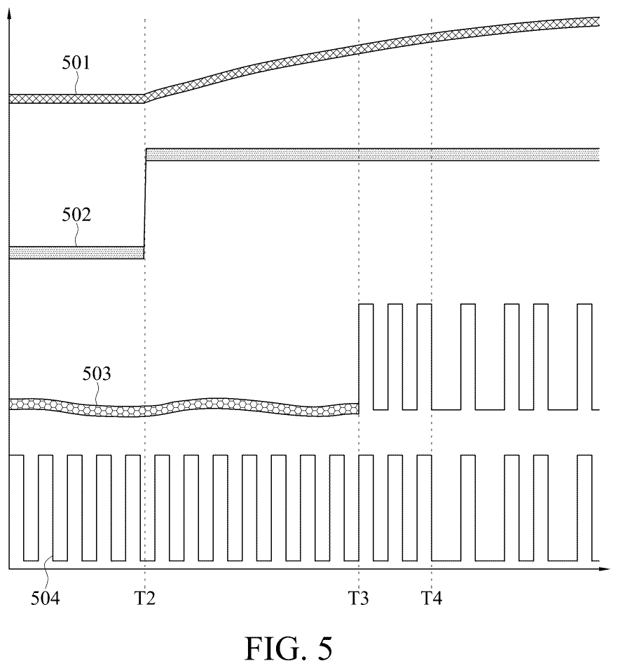

FIG. 5 illustrates a schematic view showing signal switching according to an exemplary embodiment of the instant disclosure. Refer to FIG. 3, FIG. 5, and FIG. 8. Following the embodiment shown in FIG. 4, the signal 501 is the signal received by the control terminal 3031 of the second switching element 303, the signal 502 is the output signal of the low dropout regulator 1040, the signal 503 is a signal received by the input terminal 3032 of the second switching element 303 which is outputted from the digital microphone 203, and the signal 504 is the output signal of the output terminal 3034 of the second switching element 303.

After the mode selection element 101 outputs the second signal to the switching element 102 receiving the startup signal (the step S801), as the signal 502 shown in FIG. 5, the low dropout regulator 1040 starts outputting the output voltage at the time T2 (the step S802). At this moment, the signal received by the control terminal 3031 of the second switching element 303 is the voltage on the second terminal 20112 of the resistor element 2011, and as illustrated by the signal 501, the voltage on the second terminal 20112 of the resistor element 2011 starts to increase at the time T2. The voltage on the second terminal 10312 of the resistor element 1031 reaches the second voltage at the time T4 (the step S803), wherein the time difference between the time T4 and the time T2 is the second delay time. As illustrated by the signal 503, at the time T2, the digital microphone 203 receives the output voltage of the low dropout regulator 1040 to start operation, while the digital microphone 203 starts outputting stable signals aft the time T3. As illustrated by the signal 504, at the time T4, the second switching element 303 connects the output terminal 3034 to the input terminal 3032 to switch to outputting the signal outputted by the digital microphone 203 (that is, the digital source signal) (the step S804). Because the time T4 is after the time T3, the output terminal 3034 of the second switching element 303 does not output unstable signals of the digital microphone 203, wherein the time interval between the time T3 and the time T4 is the startup time of the digital microphone 203.

While the instant disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A signal processing system comprising:
a mode selection element configured to execute, in response to receiving a turn-off signal, outputting a first signal;
a switching element coupled to the mode selection element, wherein the switching element is configured to, in response to receiving the first signal, switch from outputting a digital source signal to outputting a virtual signal;
a first delay element coupled to the mode selection element, wherein the first delay element is configured to, in response to receiving the first signal, output a first delay signal, wherein the first delay signal reaches a first voltage after a first delay time; and
a power element coupled to the first delay element, wherein the power element is configured to, in response to that the first delay signal reaches the first voltages, stop outputting an output voltage.

2. The signal processing system according to claim 1, wherein the virtual signal is a frequency-dividing signal of a system clock signal.

3. The signal processing system according to claim 2, wherein the signal processing system comprises a frequency-dividing element, the frequency-dividing element is configured to perform a dividing operation on the system clock signal based on a divisor to obtain the frequency-dividing signal, and wherein the divisor is a power of 2.

4. The signal processing system according to claim 1, wherein the mode selection element is configured to, in response to receiving a startup signal, output a second signal; the first delay element is configured to, in response to receiving the second signal, output a delayed startup signal, wherein the delayed startup signal reaches a startup voltage after a delayed startup time; the power element is configured to, in response to that the delayed startup signal reaches the startup voltage, start outputting the output voltage; the signal processing system comprises a second delay element coupled to the power element, the second delay element is configured to, in response to that the power element starts outputting the output voltage, output a second delay signal, wherein the second delay signal reaches a second voltage after a second delay time; and the switching element is configured to, in response to receiving the second signal, execute: in response to that the second delay signal reaches the second voltage, outputting the digital source signal.

5. The signal processing system according to claim 4, wherein the switching element comprises:
a first switching element coupled to the mode selection element and the second delay element, wherein the first switching element is configured to execute, in response to receiving the first signal, outputting the first signal, and in response to receiving the second signal, outputting the second delay signal; and
a second switching element coupled to the first switching element, wherein the second switching element is configured to execute: in response to receiving the first signal from the first switching element, switching to outputting the virtual signal, and in response to that the second delay signal reaches the second voltage, outputting the digital source signal.

6. The signal processing system according to claim 4, wherein the second delay element comprises a resistor element and a capacitor element, a first terminal of the resistor element is coupled to the power element, a second terminal of the resistor element is coupled to a first terminal of the capacitor element, a second terminal of the capacitor element is coupled to a ground terminal, and the second terminal of the resistor element outputs the second delay signal in response to that the power element starts outputting the output voltage.

7. The signal processing system according to claim 4, wherein the second delay time is greater than a startup time of a digital microphone.

8. The signal processing system according to claim 1, wherein the digital source signal is a digital audio signal generated by a digital microphone.

9. The signal processing system according to claim 1, wherein the first delay element comprises a resistor element and a capacitor element, a first terminal of the resistor element is coupled to the mode selection element, a second terminal of the resistor element is coupled to a first terminal of the capacitor element and a voltage source, a second terminal of the capacitor element is coupled to a ground terminal, and the second terminal of the resistor element, in response to receiving the first signal, outputs the first delay signal.

10. The signal processing system according to claim 1, wherein the power element comprises a low dropout regulator, an enable terminal of the low dropout regulator is coupled to the first delay element, and the low dropout regulator is configured to, in response to that a voltage received by the enable terminal of the low dropout regulator reaches the first voltage, stop outputting the output voltage.

11. A signal processing method adapted for a signal processing system, wherein the signal processing system comprises a mode selection element; a switching element coupled to the mode selection element; a first delay element coupled to the mode selection element; and a power element coupled to the first delay element; the signal processing method comprises:
(a1) in response to receiving a turn-off signal, outputting a first signal by the mode selection element;
(a2) in response to receiving the first signal, switching from outputting a digital source signal to outputting a virtual signal by the switching element;
(a3) in response to receiving the first signal, outputting a first delay signal by the first delay element, wherein the first delay signal reaches a first voltage after a first delay time; and
(a4) in response to that the first delay signal reaches the first voltage, stop outputting an output voltage by the power element.

12. The signal processing method according to claim 11, wherein the virtual signal is a frequency-dividing signal of a system clock signal.

13. The signal processing method according to claim 12, wherein the signal processing system comprises a frequency-dividing element, and the signal processing method comprises performing a dividing operation on the system clock signal based on a divisor to obtain the frequency-dividing signal by the frequency-dividing element, and wherein the divisor is a power of 2.

14. The signal processing method according to claim 11, wherein the signal processing system comprises a second delay element coupled to the power element; the signal processing method comprises:
(b1) in response to receiving a startup signal, outputting a second signal by the mode selection element;
(b2) in response to receiving the second signal, outputting a delayed startup signal by the first delay element, wherein the delayed startup signal reaches a startup voltage after a delayed startup time; and in response to that the delayed startup signal reaches the startup voltage, starting outputting the output voltage by the power element;
(b3) in response to that the power element starts outputting the output voltage, outputting a second delay signal by the second delay element, wherein the second delay signal reaches a second voltage after a second delay time; and
(b4) executing, in response to that switching element receives the second signal, by the switching element: outputting the digital source signal in response to that the second delay signal reaches the second voltage.

15. The signal processing method according to claim 14, wherein the switching element comprises a first switching element coupled to the mode selection element and the second delay element; and a second switching element coupled to the first switching element; the signal processing method comprises:
executing by the first switching element: in response to that the first switching element receives the first signal, outputting the first signal; and in response to that the first switching element receives the second signal, outputting the second delay signal; and
executing by the second switching element: in response to receiving the first signal from the first switching element, switching to outputting the virtual signal; and in response to that the second delay signal reaches the second voltage, outputting the digital source signal.

16. The signal processing method according to claim 14, wherein the second delay element comprises a resistor element and a capacitor element, a first terminal of the resistor element is coupled to the power element, a second terminal of the resistor element is coupled to a first terminal of the capacitor element, and a second terminal of the capacitor element is coupled to a ground terminal; the step (b2) comprises: in response to that the power element starts outputting the output voltage, outputting the second delay signal by the second terminal of the resistor element.

17. The signal processing method according to claim 14, wherein the second delay time is greater than a startup time of a digital microphone.

18. The signal processing method according to claim 11, wherein the digital source signal is a digital audio signal generated by a digital microphone.

19. The signal processing method according to claim 11, wherein the first delay element comprises a resistor element and a capacitor element, a first terminal of the resistor element is coupled to the mode selection element, a second terminal of the resistor element is coupled to a first terminal of the capacitor element and a voltage source, and a second terminal of the capacitor element is coupled to a ground terminal; the step (a3) comprises: in response to that the second terminal of the resistor element receives the first signal, outputting the first delay signal by the second terminal of the resistor element.

20. The signal processing method according to claim 11, wherein the power element comprises a low dropout regulator, and an enable terminal of the low dropout regulator is coupled to the first delay element; the signal processing method comprises: in response to that a voltage received by the enable terminal of the low dropout regulator reaches the first voltage, stopping outputting the output voltage by the low dropout regulator.
